(19) United States
(12) Patent Application Publication
(10) Pub. No.: US 2011/0146778 A1
(43) Pub. Date: Jun. 23, 2011

(54) SHIELDING OF INTERIOR DIODE ASSEMBLIES FROM COMPRESSION FORCES IN THIN-FILM PHOTOVOLTAIC MODULES

(75) Inventors: Steven Thomas Croft, Menlo Park, CA (US); Kedar Hardikar, San Jose, CA (US); Whitfield Gardner Halstead, Palo Alto, CA (US); Shawn Everson, Fremont, CA (US)

(73) Assignee: MIASOLE, Santa Clara, CA (US)

(21) Appl. No.: 12/644,360

(22) Filed: Dec. 22, 2009

(51) Int. Cl. H01L 31/00; H01L 21/56; H01L 31/0203

(52) U.S. Cl. 136/256; 438/64; 257/E21.502; 257/E31.117

(57) ABSTRACT

A method and apparatus for protecting a diode assembly of a photovoltaic module from compressive and tensile forces by providing at least one interior shielding element are provided. According to various embodiments, a photovoltaic module including a first encasing layer, a second encasing layer, at least one photovoltaic cell disposed between the first and second encasing layers, at least one shielded diode assembly disposed on the at least one photovoltaic cell and electrically connected to the at least one photovoltaic cell, and a pottant disposed between the at least one photovoltaic cell and the second encasing layer is provided. A localized shielding element may be used to shield the diode assembly.

### FIELD OF THE INVENTION

The present invention relates generally to the field of photovoltaic devices, and specifically to shielding elements configured to provide protection to diode assemblies from compression forces.

### BACKGROUND OF THE INVENTION

Photovoltaic modules commonly comprise electrical components configured to connect photovoltaic cells to one another and to power-collecting devices.

### SUMMARY OF SPECIFIC EMBODIMENTS

One embodiment of the present invention provides a photovoltaic module comprising a first encasing layer, a second encasing layer, at least one photovoltaic cell disposed between the first and second encasing layers, at least one shielded diode assembly disposed on the at least one photovoltaic cell and electrically connected to the at least one photovoltaic cell, and a pottant disposed between the at least one photovoltaic cell and the second encasing layer.

Another embodiment of the present invention provides a method of shielding a diode assembly from compression forces by providing at least one shielding element in the form of a preformed spacer disposed proximate to the diode.

Another embodiment of the present invention provides a method of shielding a diode assembly from compression forces by providing a shielding element in the form of a low durometer barrier either disposed on or fully encapsulating the leadframe portion of the diode assembly.

Another embodiment of the present invention provides a method of shielding a diode assembly from compression forces by providing a shielding element in the form of a high durometer barrier that fully encapsulates the leadframe portion of the diode assembly.

### BRIEF DESCRIPTION OF THE DRAWINGS

FIG. 1 is a cross-sectional view of a photovoltaic module comprising a diode assembly with external compression forces applied on the encasing layers.

FIG. 2 is a cross-sectional view of a photovoltaic module comprising a tensioned diode assembly and another photovoltaic module comprising a compressed diode assembly.

FIG. 3 is a cross-sectional view of a photovoltaic module comprising a diode assembly with a preformed spacer disposed proximate to the diode.

FIG. 4 is a top view of a diode assembly with an annular preformed spacer disposed around the leadframe portion of the diode assembly.

FIG. 5 is a perspective view of one embodiment of a preformed spacer comprising an annular shape consistent with that shown in FIG. 4.

FIG. 6 is a perspective view of an alternative embodiment of a preformed spacer comprising a rectangular shape.

FIG. 7 is a perspective view of yet another embodiment of a preformed spacer comprising a square U-shape.

FIG. 8 is a top view of a diode assembly with an alternative embodiment of a preformed spacer comprising a solid square shape disposed proximate to the leadframe portion of the diode assembly.

FIG. 9 is a top view of a diode assembly with an alternative embodiment of a preformed spacer comprising a rail shape disposed proximate to the diode assembly.

FIG. 10 is a cross-sectional view of a photovoltaic module comprising a diode assembly with a low durometer barrier disposed on the leadframe portion of the diode assembly.

FIG. 11 is a top view of a diode assembly with a low durometer barrier disposed on and around the leadframe portion of the diode assembly.

FIG. 12 is a cross-sectional view of a photovoltaic module comprising a diode assembly with a low durometer barrier disposed between a leadframe portion of the diode assembly and the second encasing layer.

FIG. 13 is a flow diagram illustrating certain operations in a method of fabricating a photovoltaic module including a rigid diode assembly shielding element according to certain embodiments.

FIG. 14 is a flow diagram illustrating certain operations in a method of fabricating a photovoltaic module including a low Durometer barrier shielding element according to certain embodiments.

### DETAILED DESCRIPTION OF PREFERRED EMBODIMENTS

Photovoltaic modules commonly comprise a plurality of photovoltaic cells that are electrically interconnected to each other and to energy-collecting circuitry to facilitate the collection of energy. Electrical interconnections that link photovoltaic cells to one another or to energy-collecting circuitry may comprise components such as diodes that are in electrical communication with further electrical components such as leads. In certain embodiments, a diode is connected to at least one lead which may be secured with at least one solder joint. For the purposes of the present disclosure, the diode and one or more leads and connecting joints, if present, will be termed a diode assembly. In certain embodiments, the diode assemblies are commercially available diodes.

While many photovoltaic modules comprise diode assemblies on exterior surfaces, diode assemblies may also be incorporated into interior portions of photovoltaic modules. Interior diode assemblies can be subject to significant compression forces, particularly in flexible photovoltaic modules, resulting from both compression forces imposed on the exterior of the module and compression forces resulting from expansion and contraction of pottants within the photovoltaic module during temperature changes.

Compression forces imposed on the exterior of the photovoltaic module, by factors such as adverse weather conditions or by objects striking the module, can transfer those compression forces to the interior diode assembly causing the solder joint to crack or break, compromising the integrity of the module's electrical connections.

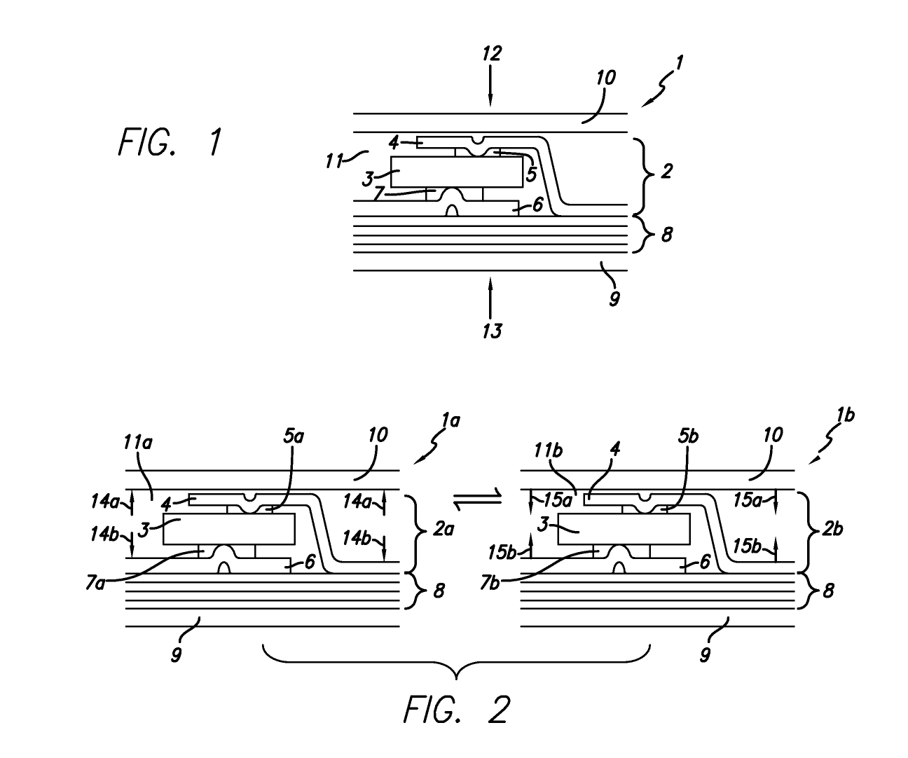

FIG. 1 shows a cross-sectional view of a photovoltaic module 1 comprising a diode assembly 2. The diode assembly 2 comprises a diode 3 in electrical communication with a first lead 4 wherein the diode 3 is affixed to the first lead 4 by a first solder joint 5. The diode 3 is further electrically connected to a second lead 6 and is affixed to the second lead 6 by a second solder joint 7. The photovoltaic module 1 further comprises a first encasing layer 9 and a second encasing layer 10. At least one photovoltaic cell 8 is disposed between the first and second encasing layers 9, 10 and at least one diode assembly 2 is disposed between the at least one photovoltaic cell 8 and the second encasing layer 10. The at least one diode assembly 2 is further electrically connected to the at least one photovoltaic cell 8. The first encasing layer 9 may be rigid or flexible, comprising a transparent material including but not limited to glass, plastic, or fiberglass. The second encasing layer 10 may also be rigid or flexible, comprising materials including but not limited to glass, plastic, metal, or fiberglass. A pottant 11 is disposed between the at least one photovoltaic cell 8 and the second encasing layer 10 filling the space that is not occupied by the at least one diode assembly 2. The pottant 11 is an electrically insulative material that generally covers substantially all of the photovoltaic module area. Examples of pottants materials include polyurethanes, ethylene vinyl acetate (EVA), polyvinyl butyral (PVB), fluoropolymers, silicones, or other electrically insulative materials. In many embodiments, the pottant material is a thermosetting material. Although not depicted, a transparent pottant layer may be present between the at least photovoltaic cell 8 and the first encasing layer 9. Representative directions of compression forces that may be placed on the exterior of the photovoltaic module are illustrated by arrows 12 and 13. When compression forces are applied to the exterior of the first or second encasing layers 9, 10, those forces may be transferred to the interior of the module, exerting force on the diode assembly 2. These forces may cause cracking or breaking of the first and second solder joints 5, 7.

Interior diode assemblies 2 may also experience mechanical stress during temperature changes. This mechanical stress can be primarily attributed to the expansion and contraction of the pottant 11. The pottant 11 may comprise materials including but not limited to low-density polyethylene that provide electrical insulation to the module's electrical interconnections. A photovoltaic module 1 may be subjected to extreme temperature changes such as dramatic weather changes or during processes such as thermal cycling, a process in which the photovoltaic module is alternately subjected to both high and low temperatures as a method of testing the durability of the module and its components. During these temperature changes, the pottant 11 expands and contracts causing the first and second encasing layers 9, 10 be forced outward and inward which can place stress on the solder joints 5, 7 of the diode assembly 2, causing them to crack or break if not shielded.

FIG. 2 shows a cross-sectional view of a tensioned photovoltaic module 1a comprising a tensioned diode assembly 2a, including solder joints 5a and 7a, as well as a compressed photovoltaic module 1b comprising a compressed diode assembly 2b, including solder joints 5b and 7b. The tensioned diode assembly 2a experiences tensile forces due to the expansion of the pottant 11a during temperature increases. Expansion of the pottant 11a causes the first and second encasing layers 9, 10 to be forced outward, placing strain on the diode assembly 2a. The directions of tensile forces imposed by expansion of the pottant 11a are represented by arrows 14a and 14b. Conversely, the compressed diode assembly 2b experiences compression forces due to the contraction of the pottant 11b which causes the first and second encasing layers 9, 10 to collapse inward and exert force on the diode assembly 2b. The directions of compression forces imposed by contraction of the pottant 11b are represented by arrows 15a and 15b.

A diode assembly shielding element, such as at least one preformed spacer, a low durometer barrier, or a high durometer barrier would provide a convenient and low-cost structure for shielding an interior diode assembly from the aforementioned forces. Such a structure could re-distribute stress near the diode while being sufficiently thin so as to accommodate the limiting thickness requirements of a thin-film photovoltaic module.

While the photovoltaic module and diode assembly depicted in FIGS. 1 and 2 provide a useful context for discussion embodiments of the invention, the invention is not limited to the specific configuration of module or diode assembly components depicted. Rather, the diode assembly shielding elements described herein may be used with any interior diode assembly. The location and functionality of the module components may vary based on implementation. For example, in certain embodiments, the diode assembly may be disposed between cell 8 and encapsulating layer 9. In other embodiments, one or more additional module components may be present. Similarly, the diode assembly is not limited to the particular configuration shown. For example, the leadframe may have any appropriate shape or configuration. Moreover, certain embodiments of the invention is not limited to photovoltaic modules, but may be used for shielding any diode or other electrical assembly within planar encasing layers. In many embodiments, the diode assemblies include a diode connected via one or more solder joints to one or more leads. However, other types of diode assemblies including commercially available diodes are also within the scope of the invention.

In certain embodiments, a diode assembly shielding element may be a substantially rigid, impact and temperature resistant element. One or more such elements may be used to shield a diode assembly. As described further below, the thickness of the element is such that, in place, the diode assembly shielding element maintains sufficient space between the diode assemble and an encasing layer to prevent the encasing layer from applying substantial compression forces on the diode assembly.

According to various embodiments, a rigid shielding element may include an open region. The rigid shielding element may wholly or partially surround the entire diode assembly or a leadframe portion thereof, with the entire diode assembly or leadframe portion thereof wholly or partially within the open region. Such a leadframe portion generally includes the entire diode, and the solder joint (or other type of joint) that connects the leadframe and the diode.

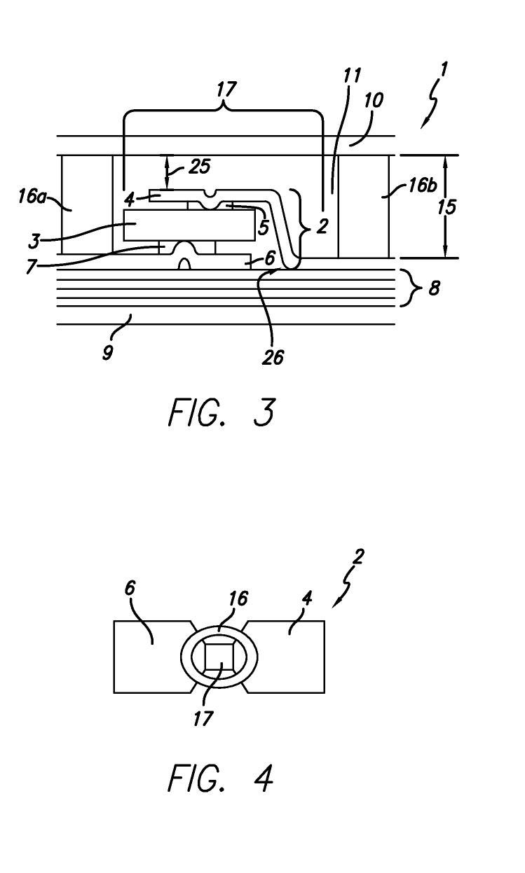

In various embodiments, the shielding element may or may not overlay the diode assembly. For example, in certain embodiments, it is not necessary for the diode assembly shielding element to cover the entire surface of the diode assembly 2 or even the leadframe portion 17 (see FIG. 3), as the shielding element would not need to provide electrical insulation, given that the interior pottant 11 provides the requisite electrical insulation. The leadframe portion 17 (FIG. 3) for the purposes of this embodiment comprises a portion of the diode assembly 2 that includes the entire diode 3, as well as the portion of the first lead 4 that engages the diode 3 up to and including the bent portion 26 and the portion of the second lead 6 that is disposed below the diode 3. The shielding element may be in the form of at least one preformed spacer that substantially prevents the first and second encasing layers 9, 10 from exerting force on the diode assembly.

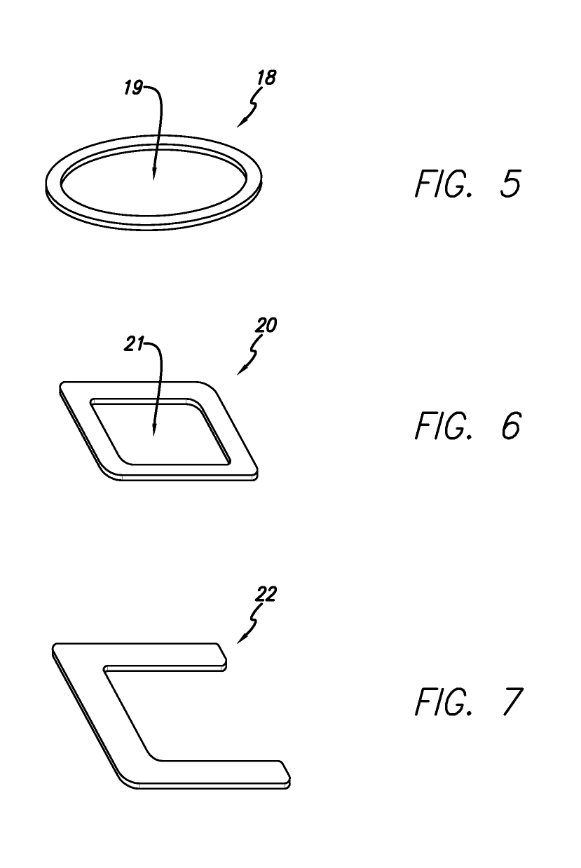

FIG. 3 shows a cross-sectional view of a photovoltaic module 1 comprising a diode assembly 2 and further comprising a preformed spacer (not fully shown, but cross sectional portions 16a and 16b represent portions of the preformed spacer with an embodiment consistent with that shown in FIG. 5). The preformed spacer (not fully shown) maintains sufficient space between the at least one photovoltaic cell 8 and the second encasing layer 10 to keep the second encasing layer 10 from applying substantial compression forces on the diode assembly 2. The preformed spacer (not fully shown) may either be affixed in its position by a substance such as glue, or it may simply rest in its position without being affixed to any portion of the photovoltaic module 1.

Unlike the pottant material, the preformed spacer or other shielding element covers only a localized area of the photovoltaic module, typically associated with a single diode assembly. For example, a single shielding element may overlay no more than about 10% of the photovoltaic module, in certain embodiments. In many embodiments, a single shielding element is much smaller, e.g., overlaying no more than about 5%, 1%, 0.5%, 1%, 0.5%, 0.1%, 0.05%, 0.01%, or 0.005% of the module area. In cases wherein each diode is associated with multiple shielding elements, the multiple shielding elements associated with a single diode may together overlay no more than about 10%, 5%, 1%, 0.5%, 0.1%, 0.05%, 0.01%, or 0.005% of the module area. For example, a shielding element may have a top surface area of no more than about 5 cm², 2 cm², 1 cm², 0.5 cm², 0.25 cm², 0.1 cm², or 0.05 cm² for a module area of 1 m². In certain embodiments, a shielding element may have a top surface area of no more than about 1 square inch, 0.5 square inches, 0.25 square inch, 0.1 square inches, 0.05 square inches, 0.025 square inches, or 0.01 square inches.

In certain embodiments, modules include multiple diodes each associated with one or more shielding elements. A diode may be associated with one or more photovoltaic cells. According to various embodiments, all shielding elements in the module may together overlay no more than about 10%, 5% or 1% of the module area.

Also as described further below, in certain embodiments, a single shielding element such as a rail may be associated with multiple diode assemblies. Such a shielding element may overlay no more than about 10%, 5%, 1%, 0.5%, 0.1%, 0.05%, 0.01%, or 0.005% of the module area.

As used herein, the term “localized shielding element” is used to refer to a shielding element the entirety of which is within about 15 inches of at least one diode assembly. In certain embodiments, the entirety of a localized shielding element is within about 10 inches of at least one diode assembly. In certain embodiments, the entirety of a localized shielding element is within about 8 inches, 6 inches, 5 inches, 4 inches, 3 inches, 2 inches, 1.5 inches, 1.25 inches, 1 inch, 0.5 inches, 0.25 inches, 0.1 inches, or 0.05 inches of at least one diode assembly.

The preformed spacer should be thin enough so as to not add thickness to the portion of the module disposed between the at least one photovoltaic cell 8 and the second encasing layer 10. In some thin-film photovoltaic modules, the total thickness of the portion of the module disposed between the at least one photovoltaic cell 8 and the second encasing layer 10 may be between about 0.01 and 0.03 inches, such as between 0.019 and 0.030 inches, for example 0.025 inches. The thickness of the preformed spacer is such that the preformed spacer maintains a thickness 25 between the leadframe portion 17 and the second encasing layer 10 of between about 0.001 and 0.011 inch. Thus the preformed spacer could have a thickness between about 0.020 and 0.030 inch thick, such as between about 0.020 and 0.025 inch, for example 0.023 inch, depending on the embodiment employed. The thickness of the preformed spacer is illustrated in FIG. 3 wherein the cross-sectional portions 16a, 16b have a thickness 15.

The preformed spacer should comprise a substantially rigid impact and temperature resistant material. For the purposes of the present disclosure, a substantially rigid material means a material with a durometer value between 70 to 150 Rockwell hardness, such as between 80 and 120 Rockwell hardness. The material should also be temperature resistant, that is, substantially resistant to expansion or contraction during exposure to temperatures ranging from −40 to +90 degrees Celsius.

A polycarbonate material is an example of a material that could be used in a preformed spacer as it is both impact resistant and temperature resistant. While polycarbonate is one example of a preferred material, it should be recognized that other materials are within the scope of the present invention. Other engineering plastics may be used such as acrylonitrile butadiene styrene (ABS), polyamides, polybutlene terephthalate (PBT), polysulphone (PSU), polyetherketone (PEK), polyimides, and polyphenylene oxide (PPO), nylon (e.g., nylon 6.6), polyethylene terephthalate (PET) and other polyesters, fluoropolymers, silicones, polyether ether ketone (PEEK) and polysulfones. The preformed spacer may comprise a shape that either surrounds or partially surrounds the diode.

In certain embodiments in which the preformed spacer wholly or partially surrounds only a leadframe portion of the diode assembly, the preformed spacer overlays or rests upon one or more surfaces of the leads. In many such embodiments, these surfaces are flat and co-planar, and may be in a plane parallel to that of the encasing layers. For example, in the embodiment depicted in FIG. 3, cross sectional portions 16a and 16b of a preformed spacer are depicted as overlaying flat and co-planar surfaces of leads 4 and 6. In other the embodiments, the preformed spacer wholly or partially surrounds the entire diode assembly.

FIG. 4 shows a top view of a diode assembly 2 with an annular preformed spacer 16 in accordance with one embodiment of the present invention disposed thereon. The annular preformed spacer 16 is placed in such a way so as to surround the leadframe portion 17 to maximize shielding of the diode assembly.

FIG. 5 shows a perspective view of a preformed spacer in accordance with the present invention consistent with the embodiment shown in FIG. 4. The preformed spacer 18 is a pre-fabricated structure with an annular shape having an open region 19 in the center configured to allow the preformed spacer 18 to surround the leadframe portion 17 of the diode assembly 2.

FIG. 6 shows an alternative embodiment of a preformed spacer in accordance with the present invention. The preformed spacer 20 has a square shape with a rectangular/square-shaped opening 21 in the center. The square-shaped opening 21 is configured to allow the preformed spacer 20 to surround the leadframe portion 17 of the diode assembly 2. As indicated, in certain embodiments, the preformed spacer 18 in FIG. 5 or 20 in FIG. 6 is large enough to surround the entire diode assembly.

In addition to the circular and rectangular shapes depicted, the preformed spacers may have any appropriate shape including an open region in which all or a portion of the diode assembly may fit.

FIG. 7 shows yet another embodiment of a preformed spacer in accordance with the present invention. The preformed spacer 22 has a squared U-shape that is capable of surrounding the leadframe portion 17 on three sides. This squared U-shape may be easier to manufacture and requires less material than the aforementioned embodiments. In alternate embodiments, the preformed spacer is configured to surround the diode assembly or a portion thereof on two sides. As with the shielding elements depicted in FIGS. 5 and 6, the preformed spacer 22 may or may not overlay one or more surfaces of the diode assembly.

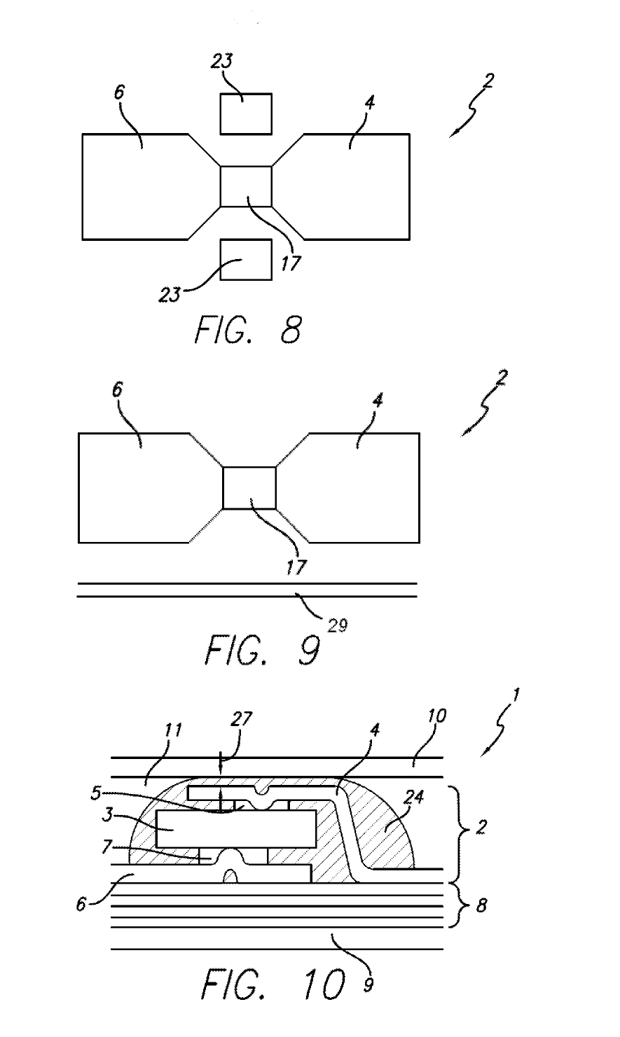

FIG. 8 shows an alternative embodiment of a preformed spacer in accordance with the present invention. In this embodiment, the preformed spacers 23 are a solid rectangular/square shape and are disposed proximate to the leadframe portion 17 in such a way that they are not in contact with either the first or second leads 4, 6. This embodiment could be beneficial in configurations in which damage could be caused to the solder joints 5, 7 if a preformed spacer were placed directly on the first and second leads 4, 6, such as configurations in which solder joints are particularly vulnerable to damage. Examples of such configurations include cases where leads 4, 6 are made of a stiff material that transfers more of the applied force directly to the solder joint. If compression forces were applied by an encasing layer to an embodiment as shown in FIG. 8, the compression forces would be transferred to the preformed spacer 23 and subsequently to the at least one photovoltaic cell 8 minimizing damage to the diode assembly 2.

Preformed spacers that are disposed proximate to and do not contact the diode assembly may be any appropriate shape, including squares, rectangles, circles, etc. In many embodiments, the preformed spacers are solid and do not have any openings therein, though other embodiments may be used as appropriate. In certain embodiments, the preformed spacers may be disposed adjacent to the edges of the diode from which the leads do not extend. For example, in FIG. 8, leads 4 and 6 extend out from leadframe portion 17 on opposite sides and preformed spacers 23 are disposed adjacent to leadframe portion 17 on opposite sides.

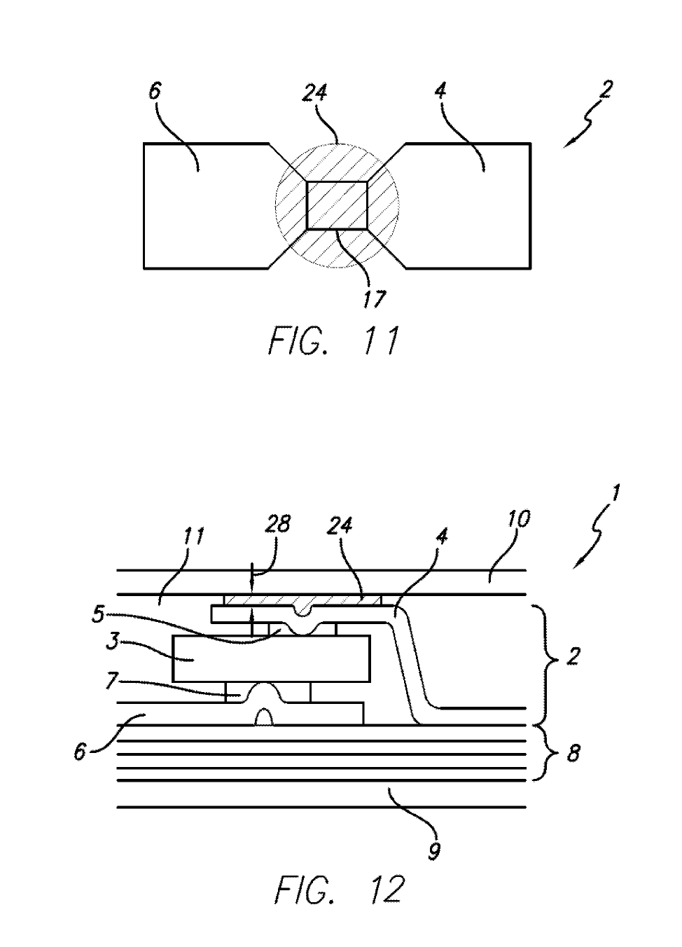

FIG. 9 shows yet another alternative embodiment of a preformed spacer in accordance with the present invention. In this embodiment, the preformed spacer 29 comprises a rail shape and is disposed proximate to the diode assembly 2. According to various embodiments, the preformed spacer 29 may be shorter than, co-extensive with, or longer than diode assembly 2. One or more such preformed spacer 29 may be used to shield multiple diode assemblies in certain embodiment.

In certain embodiments, multiple rigid shielding elements may be connected with a rigid or non-rigid connector, with each shielding element approximately aligned with a diode assembly, such that the shielding element partially or wholly covers its respective diode assembly, wholly or partially surrounds its respective diode assembly, or lies adjacent to its respective diode assembly.

In certain embodiments, multiple preformed spacers are use to shield a single diode assembly. For example, concentric rings may be used in one embodiment. In another example, two L-shaped spacers that each partially surrounds the diode assembly or leadframe portion thereof may be used. In yet another example, two preformed rail-shaped spacers may be disposed lengthwise on opposite sides of the diode assembly.

While various embodiments of preformed spacers have been described herein, it should be recognized that other embodiments may be imagined that are fully within the scope of the invention.

In alternate embodiments, shielding of the diode assembly 2 is accomplished by providing a protective shielding element in the form of a low durometer barrier either disposed on or fully encapsulating the leadframe portion 17 of the diode assembly 2 to shield the assembly from force exerted by the first and second encasing layers 9, 10. In certain embodiments, the low durometer barrier comprises material that has a high melting point, such as between about 200 and 2000° C., for example between about 300 and 500° C. to assure that the material retains its shape during vacuum lamination while providing compliance during subsequent temperature changes. A low durometer, compliant material would substantially absorb the impact from the encasing layer by deforming without transferring significant compression forces to the diode assembly 2. In certain embodiments, the low durometer barrier comprises a material that has a higher melting point than the pottant material. In this manner, stress that arises due to temperature-based contraction or expansion of the pottant material is absorbed by the low durometer barrier.

A low durometer barrier, for the purposes of the present disclosure, means a barrier comprising a material that has a durometer value between 15 and 55 Shore A hardness, such as between 15 and 45 Shore A hardness. An example of a low durometer barrier is SS-300 Silicone which has a durometer value of 38 Shore A hardness when cured.

For ease of application, the material used to form the low durometer barrier could be fluid upon application and structurally stable upon curing. The low durometer barrier could be applied directly onto a leadframe portion 17 after the leadframe portion 17 is formed. The low durometer barrier may either fully encapsulate the leadframe portion 17 (as shown in FIGS. 10 and 11), or it could simply be disposed on the diode assembly 2 between the leadframe portion 17 and the second encapsulating layer 10 (as shown in FIG. 12). A fully encapsulated leadframe portion or fully encapsulated diode assembly generally is a leadframe portion or diode assembly in which at least the portions of the leadframe portion or diode assembly that are not in contact with photovoltaic cell 8 or other underlying layer or component.

FIG. 10 is a cross-sectional view of a photovoltaic module 1 comprising a diode assembly 2 with a low durometer barrier 24 disposed thereon. The low durometer barrier fully encapsulates the leadframe portion 17 to minimize the transfer of force applied by the first and second encasing layers 9, 10.

FIG. 11 is a top view of a diode assembly 2 with a low durometer barrier 24 disposed thereon consistent with the configuration shown in FIG. 10. As shown, the low durometer barrier fully encapsulates the leadframe portion 17 to provide maximum shielding. The low durometer barrier 24 could maintain a thickness 27 of 0.001 to 0.011 inch between the leadframe portion 17 and the second encapsulating layer 10 such as 0.001 and 0.005 inch. Therefore the overall thickness of the low durometer barrier 24 could be between 0.020 and 0.030 inch such as between 0.020 and 0.025 inch.

FIG. 12 illustrates an alternative embodiment of the present invention in which the low durometer barrier 24 is disposed only between the leadframe portion 17 of the diode assembly 2 and the second encasing layer 10. In such a configuration, the low durometer barrier could occupy a thickness 28 between about 0.001 and 0.011 inch, such as 0.001 to 0.005 inch.

Alternatively, the diode assembly shielding element may comprise a high durometer barrier that fully encapsulates the leadframe portion 17 of the diode assembly 2, similar to the configuration shown in FIGS. 10 and 11. A high durometer barrier would provide a rigid barrier between the diode assembly 2 and the second encasing layer 10. A high durometer barrier for the purposes of this embodiment means a barrier comprising a material with a durometer value between 70 to 150 Rockwell hardness, such as between 90 and 130 Rockwell hardness, such as an epoxy material. The material could be applied directly on the leadframe portion 17 after its formation. For ease of application, the material used to form the high durometer barrier could be fluid upon application and rigid/hard upon curing. An example of a suitable material that could be used to form the high durometer barrier is EPIC 0156 Epoxy that has a durometer value of 80 Rockwell hardness when cured.

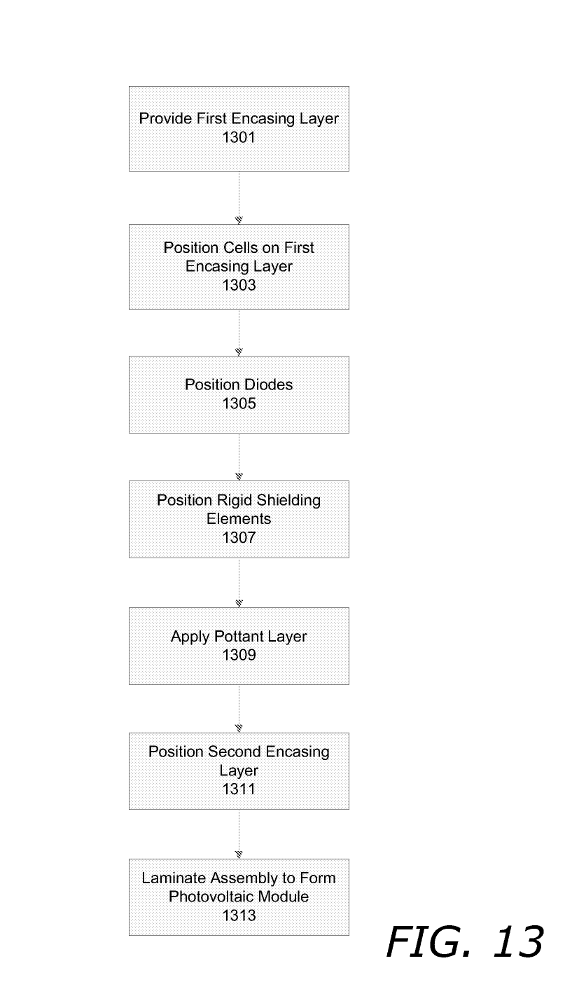

FIG. 13 is a flow chart showing certain operations in a method of fabricating a photovoltaic module including rigid shielding elements according to certain embodiments. A first encasing layer, such as a glass sheet or other transparent layer, is provided. (Block 1301). Although not depicted, one or more insulative or other materials may be placed on or applied to the first encasing layer at this point. The photovoltaic cells are then positioned on the first encasing layer. (Block 1303). One or more diode assemblies are then positioned. (Block 1305). According to various embodiments, the diode assemblies may be positioned on or adjacent to the photovoltaic cells, so long as they are electrically connected to the photovoltaic cells. In certain embodiments, multiple diode assemblies connected via connectors or a strip of metal, polymer or other material are laid out over the cells to make contact with the cell backsides. The rigid shielding elements are then positioned as described above, e.g., wholly or partially overlaying or surrounding the diode assemblies, or next to the diode assemblies. (Block 1307). In certain embodiments, the order of operations 1307 and 1305 may be reversed, or the operations may be performed simultaneously or overlap. In certain embodiments, the diode assemblies and shielding elements are associated, e.g., connected via a polymer strip, adhesive or other material prior to positioning both the assemblies and the shielding elements on the photovoltaic cells. One or more diode assemblies and their associated shielding elements may then be positioned in a single operation. In certain embodiments, one or more rail-shaped elements as described above with reference to FIG. 19 are placed near the diode assemblies. Once the diode assemblies and associated rigid shielding elements are in place, a pottant layer is applied. (Block 1309). In certain embodiments, the pottant layer is applied as a thermoplastic sheet that is heated in a subsequent processing operation to fill the space around the diode assemblies and rigid shielding elements as described above with respect to FIGS. 1 and 2. The second encasing layer is then positioned. (Block 1311). The entire assembly is then laminated to create the photovoltaic module. (Block 1313).

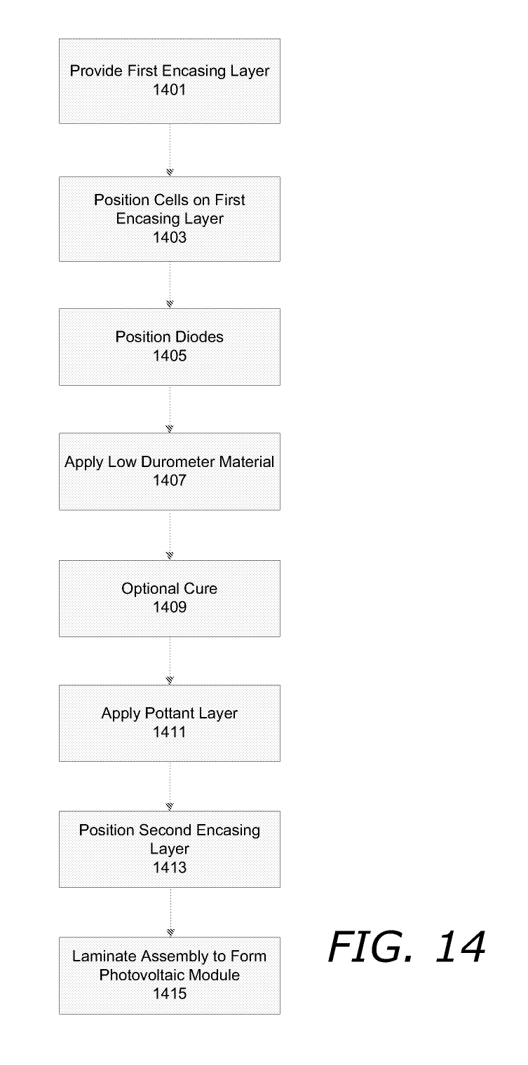

FIG. 14 is a flow chart showing certain operations in a method of fabricating a photovoltaic module including a low durometer shielding element according to certain embodiments. The first encasing layer is provided, as in the above-described process. (Block 1401). The photovoltaic cells are appropriately positioned as are the one or more diode assemblies. (Blocks 1403 and 1405). The low durometer material is then applied, e.g., by applying the material to each of the diode assemblies to encapsulate the assemblies or leadframe portions thereof as in FIGS. 10 and 11 or only on top of a top surface of the diode assembly as in FIG. 12. (Block 1407). The low durometer material may optionally be cured. (Block 1409). In certain embodiments, the low durometer material may be applied to the diode assembly prior to positioning the diode assemblies on the photovoltaic cells. Also in certain embodiments, multiple low durometer shielding elements may be connected, e.g., via a polymer strip or other connector, for easy placement. A pottant layer is then applied as described above. (Block 1411). The second encasing layer is positioned and the entire assembly is then laminated to create the photovoltaic module. (Blocks 1413 and 1415).

While the present invention has been described with reference to preferred embodiments, those skilled in the art will recognize that changes may be made in form and detail without departing from the spirit and scope of the invention.

What is claimed is:

1. A method of shielding a diode assembly of a photovoltaic module from compression forces, the method comprising:
providing a photovoltaic module comprising at least one diode assembly; and
providing at least one diode assembly localized shielding element configured to protect the diode assembly from compressive or tensile forces applied to the module.

2. The method as recited in claim 1, wherein the shielding element is a preformed spacer.

3. The method as recited in claim 2, wherein the preformed spacer comprises a substantially rigid material.

4. The method as recited in claim 3, wherein the substantially rigid material is a polycarbonate material.

5. The method as recited in claim 2, wherein the preformed spacer substantially encircles a leadframe portion.

6. The method as recited in claim 5, wherein the preformed spacer comprises an annulus.

7. The method as recited in claim 2, wherein the preformed spacer surrounds a leadframe portion on three sides.

8. The method as recited in claim 2, wherein the preformed spacer has a thickness between 0.020 and 0.030 inch.

9. The method as recited in claim 2, wherein the preformed spacer has a thickness between 0.020 and 0.025 inch.

10. The method as recited in claim 1, wherein the shielding element is a low durometer barrier.

11. The method as recited in claim 10, wherein the low durometer barrier comprises silicone.

12. The method as recited in claim 10, wherein the low durometer barrier fully encapsulates a leadframe portion.

13. The method as recited in claim 12, wherein the low durometer barrier has a thickness between 0.020 and 0.030 inch.

14. The method as recited in claim 10, wherein the low durometer barrier is disposed only between a leadframe portion and an encasing layer.

15. The method as recited in claim 14, wherein the low durometer barrier has a thickness between 0.001 and 0.011 inch.

16. The method as recited in claim 14, wherein the low durometer has a thickness between 0.001 and 0.005 inch.

17. The method as recited in claim 1, wherein the shielding element is a high durometer barrier.

18. The method as recited in claim 17, wherein the high durometer barrier comprises epoxy.

19. The method as recited in claim 17, wherein the high durometer barrier fully encapsulates a leadframe portion.

20. The method as recited in claim 19, wherein the high durometer barrier has a thickness between 0.020 and 0.030 inch.

21. The method as recited in claim 19, wherein the high durometer barrier has a thickness between 0.020 and 0.025 inch.

22. A photovoltaic module, comprising:
a first encasing layer;
a second encasing layer;
at least one photovoltaic cell disposed between the first and second encasing layers;
at least one diode assembly disposed between the at least one photovoltaic cell and the second encasing layer;
a localized shielding element configured to protect the diode assembly from compressive or tensile forces applied to the module disposed between the at least one photovoltaic cell and the second encasing layer.

23. The photovoltaic module of claim 22, wherein the shielding element is a preformed spacer.

24. The photovoltaic module of claim 23, wherein the preformed spacer comprises a substantially rigid material.

25. The photovoltaic module of claim 24, wherein the substantially rigid material is a polycarbonate material.

26. The photovoltaic module of claim 23, wherein the preformed spacer substantially encircles a leadframe portion.

27. The photovoltaic module of claim 26, wherein the preformed spacer comprises an annulus.

28. The photovoltaic module of claim 23, wherein the preformed spacer surrounds a leadframe portion on three sides.

29. The photovoltaic module of claim 23, wherein the preformed spacer has a thickness between 0.020 and 0.030 inch.

30. The photovoltaic module of claim 23, wherein the preformed spacer has a thickness between 0.020 and 0.025 inch.

31. The photovoltaic module of claim 22, wherein the shielding element is a low durometer barrier.

32. The photovoltaic module of claim 31, wherein the low durometer barrier comprises silicone.

33. The photovoltaic module of claim 31, wherein the low durometer barrier fully encapsulates a leadframe portion.

34. The photovoltaic module of claim 33, wherein the low durometer barrier has a thickness between 0.020 and 0.030 inch.

35. The photovoltaic module of claim 31, wherein the low durometer barrier is disposed only between a leadframe portion and an encasing layer.

36. The photovoltaic module of claim 35, wherein the low durometer barrier has a thickness between 0.001 and 0.0011 inch.

37. The photovoltaic module of claim 35, wherein the low durometer barrier has a thickness between 0.001 and 0.005 inch.

38. The photovoltaic module of claim 22, wherein the shielding element is a high durometer barrier.

39. The photovoltaic module of claim 38, wherein the high durometer barrier comprises epoxy.

40. The photovoltaic module of claim 38, wherein the high durometer barrier fully encapsulates a leadframe portion.

41. The photovoltaic module of claim 40, wherein the high durometer barrier has a thickness between 0.020 and 0.030 inch.

42. The photovoltaic module of claim 40, wherein the high durometer barrier has a thickness between 0.020 and 0.025 inch.

43. The photovoltaic module of claim 40, further comprising a pottant disposed between the at least one photovoltaic cell and the second encasing layer.
